(19) United States
(12) Patent Application Publication
(10) Pub. No.: US 2018/0315679 A1
(43) Pub. Date: Nov. 1, 2018

(54) Circuit cooled on two-sides

(71) Applicant: CeramTec GmbH, Plochingen (DE)

(72) Inventors: Roland DILSCH, Thierstein (DE); Harald KRESS, Langenzenn (DE)

(21) Appl. No.: 15/766,059

(22) PCT Filed: Oct. 4, 2016
(86) PCT No.: PCT/EP2016/073643

§ 371 Date: Apr. 5, 2018

(30) Foreign Application Priority Data
Oct. 7, 2015 (DE) 10 2015 219 347.0

(51) Int. Cl. H01L 23/373; H01L 23/467; H01L 23/473; H01L 23/00

(52) U.S. Cl. CPC H01L 23/3735; H01L 23/467; H01L 2224/73265; H01L 24/73; H01L 23/473

(57) ABSTRACT

The invention relates to a component (9) comprising a first ceramic substrate (1) with an upper side (1b) and a lower side (1a), wherein a metallization (2) is applied on the upper side (1b), on which metallization an Si circuit (4) is mounted by its lower side via a connecting means (3). In order that the Si circuit (4) is cooled on both sides by elements with a high thermal conductivity and simultaneously a high electrical conductivity, and in order that the efficiency of the assembly is increased, according to the invention, a connecting means (5) is applied on the upper side (1b) of the Si circuit (4), on which connecting means a ceramic flat substrate (6) is attached by its lower side, and a second ceramic substrate (8) is arranged on the flat substrate (6) via a metallization (7), wherein the ceramic flat substrate (8) contains metal-filled thermal electrical vias (11) and/or cooling ducts for conveying a cooling means.

The invention relates to a component consisting of a first ceramic substrate with an upper side and a lower side, wherein a metallization is applied to the upper side, on which metallization an electronic module is mounted by its lower side via a connecting means.

Configurations are known in which ceramic substrates of Al₂O₃ or AlN carry an at least one-sided metallization (DCB-Cu, thick film Cu, Ag, W—Ni—Au), on which, in turn, an Si circuit is fixed by pressure, solder, sintered silver, silver glue, or the like.

On the second side of the substrate, further metallization surfaces can be present, on which, for example, a heat sink made of aluminum or the like is glued or soldered. The Si circuits are therefore connected by at most one side with an electrically insulating heat sink. The upper free side of the Si circuit is, at most, gas cooled. An ‘Si circuit’ also means, in general, a chip or a transistor.

The object of the invention is to improve a component according to the preamble of claim 1 in such a manner that the Si circuit is cooled on both sides—that is, both on its lower side and on its upper side. The cooling of the Si circuit on two sides by elements with higher thermal conductivity and also higher electrical conductivity is intended to increase the efficiency of the assembly.

According to the invention, this object is achieved by a component having the features of claim 1.

Due to the fact that a connecting means is applied on the upper side of the Si circuit, on which a flat substrate is applied by its lower side, and a second ceramic substrate is arranged on the flat substrate via a metallization, wherein the ceramic flat substrate contains metal-filled thermo-electric through-connections (vias) and/or cooling ducts for the purpose of conveying a cooling means, the Si circuit is cooled on two sides—that is, both on its lower side and on its upper side. The cooling of the Si circuit on two sides by elements with higher thermal conductivity and also higher electrical conductivity is intended to increase the efficiency of the assembly of the Si circuit. The metal in the vias of the ceramic flat substrate lies both on the metallization of the second substrate and on the connecting means, which is positioned on the Si circuit.

The Si circuit is preferably a chip or a transistor.

The metallizations preferably consist of DCB-Cu, thick film Cu, Ag or W—Ni—Au and/or are metallizations sintered with the ceramic substrate. Sintered metallizations are intimately connected with the ceramic and thereby demonstrate excellent heat transport from the Si circuit into the ceramic.

The connecting means is preferably a solder, sintered silver, or silver glue.

In an embodiment according to the invention, the vias are made of Cu or Ag, and the substrates are made of aluminum nitride. Aluminum nitride possesses high thermal conductivity.

In one embodiment, cooling elements such as fins or the like are arranged on the lower side of the first ceramic substrate.

A better heat dissipation on two sides can be achieved by means of the ceramic flat substrate with metal-filled vias, which contacts the free upper side of the Si circuit via the connecting means. This flat substrate contains metal-filled thermo-electric through-connections (vias), which are filled, for example, with Cu or Ag. If aluminum nitride is selected as the substrate material, the coefficient of expansion thereof, of about 4.7 ppm/K, is close to that of the silicon of the chip, at about 4.2 ppm/K.

These via ceramics (flat substrates) can be connected both on the side of the Si circuit and on the other side with the metallized ceramic substrate, via solder, silver paste or a silver sintered layer on a second ceramic substrate, and/or by burning the copper paste directly into the copper layer of the metallized upper substrate.

To further increase the heat dissipation, instead of ceramic flat substrates, ceramic coolers through which liquid flows, or the same with ceramic fins, can be used.

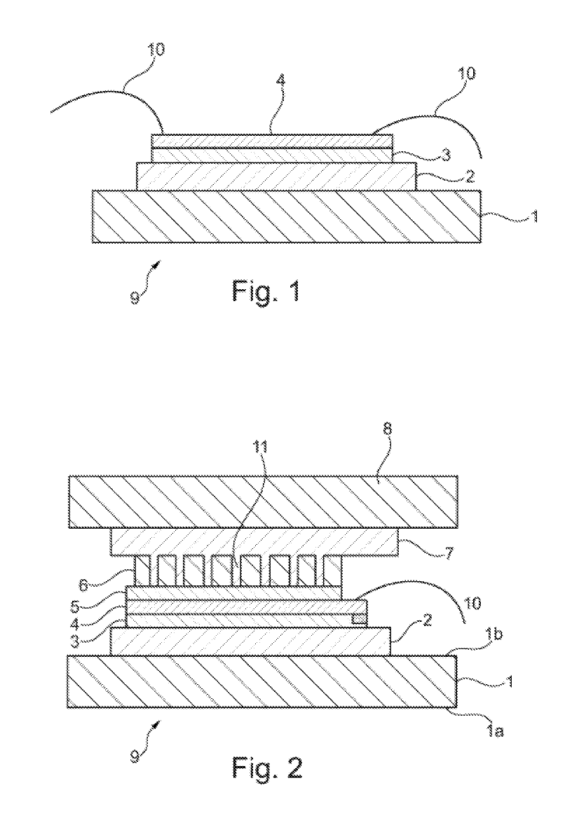

The figures show the prior art (FIG. 1) and a component according to the invention (FIG. 2).

FIG. 1 shows a component 9 according to the prior art. The component consists of a first ceramic substrate 1 with an upper side 1b and a lower side 1a, wherein a metallization 2 is applied on the upper side 1b, wherein an Si circuit 4 is mounted on the same by its lower side via a connecting means 3. According to the invention, on the Si circuit 4 and/or on its upper side, a ceramic flat substrate 6 is attached by its lower side via a connecting means 5, and a second ceramic substrate 8 is arranged on the flat substrate 6 via a metallization 7, wherein the ceramic flat substrate 6 contains metal-filled thermo-electric through-connections (vias) 11 and/or cooling ducts used to convey a cooling means.

The ceramic substrates 1, 8 are preferably plate-shaped and preferably are made of aluminum nitride, which has a very high thermal conductivity.

The metallizations preferably consist of DCB-Cu, thick film Cu, Ag or W—Ni—Au and/or are sintered with the ceramic substrate 1, 8.

The Si circuit 4 is a silicon circuit designed as a chip or a transistor.

The connecting means 3, 5 are preferably solder, sintered silver or silver glue.

The through-connections 11 are made of Cu or Ag, by way of example.

Cooling elements, which are not shown in FIG. 2, are preferably arranged on the lower side 1a of the first ceramic substrate 1. These cooling elements can be fins used for air cooling. However, they can also be cool boxes which convey liquid.

The ceramic flat substrate 6 is used to lead away the waste heat of the Si circuit 4 into the ceramic substrate 8, and can also be used to electrically couple the Si circuit 4 to the metallization 7. The flat substrate 6 is also preferably made of aluminum nitride. The waste heat is transported, and an electrical connection is made, by its metal-filled thermo-electric through-connections (vias) 11. The through-connections (vias) 11 preferably run at right angles to the surface of the flat substrate 6.

The reference numeral 10 is used in both figures to indicate bond wires used to create electrical connections.

1. A component consisting of a first ceramic substrate with an upper side and a lower side, wherein a metallization is applied on the upper side, on which metallization an Si circuit is mounted by its lower side via a connecting means, wherein a connecting means is applied on the upper side of the Si circuit, on which connecting means a ceramic flat substrate is attached by its lower side, and a second ceramic substrate is arranged on the flat substrate via a metallization, wherein the ceramic flat substrate contains metal-filled thermo-electric through-connections (vias) and/or cooling ducts to convey a cooling means.

2. The circuit according to claim 1, wherein Si circuit is a silicon circuit, a chip, or a transistor.

3. The circuit according to claim 1, wherein all metallizations are made of DCB-Cu, thick film Cu, Ag or W—Ni—Au, and/or are metallizations which are sintered with the ceramic substrate.

4. The circuit according to claim 1, wherein the connecting means are solder, sintered silver, or silver glue.

5. The circuit according to claim 1, wherein the through-connections are made of Cu or Ag and the substrates are made of aluminum nitride.

6. The circuit according to claim 1, wherein cooling elements are arranged on the lower side of the first ceramic substrate.
